(19) United States
(12) Patent Application Publication
(10) Pub. No.: US 2023/0187510 A1
(43) Pub. Date: Jun. 15, 2023

(54) ANGLED VIA FOR TIP TO TIP MARGIN IMPROVEMENT

(71) Applicant: International Business Machines Corporation, Armonk, NY (US)

(72) Inventors: Ruilong Xie, Niskayuna, NY (US); Oleg Gluschenkov, Tannersville, NY (US); Eric Miller, Watervliet, NY (US); Yasir Sulehria, Niskayuna, NY (US)

(21) Appl. No.: 17/551,829

(22) Filed: Dec. 15, 2021

(51) Int. Cl. H01L 29/417; H01L 27/092; H01L 21/8238; H01L 29/423; H01L 29/40; H01L 29/66; H01L 29/786; H01L 29/06

(52) U.S. Cl. CPC H01L 29/41733; H01L 27/092; H01L 21/823814; H01L 21/823871; H01L 29/42392; H01L 29/401; H01L 29/66742; H01L 29/78618; H01L 29/0665; H01L 23/5226

(57) ABSTRACT

Embodiments disclosed herein include a semiconductor structure having a first lower device and a second lower device laterally adjacent to the first lower device at a lower level of the semiconductor structure, a first upper device and a second upper device laterally adjacent to the first upper device at an upper level of the semiconductor structure. The upper level may be vertically above the lower level. The semiconductor structure may also include an angled via electrically connecting the lower device and the first upper device. The angled via may include an angled surface laterally between the first upper device and the second upper device that is angled toward the first upper device relative to a vertical axis.

### BACKGROUND

The present invention relates generally to the field of semiconductor device manufacturing, and more particularly to fabricating a semiconductor structure with an angled via that improves a tip to tip distance between contacts.

Semiconductor devices are fabricated these days as a plurality of integrated circuits built up in layers on a substrate. A complex network of signal paths between these layers can be routed to connect the lower level devices to the circuit elements distributed on the surface of the integrated circuit wafer. Efficient routing of these signal paths can include the formation of multilevel or multilayered interconnect schemes (e.g., single or dual damascene wiring structures) during the back-end-of-line (BEOL) phase of manufacturing. In addition to signal paths, power can be distributed by interconnect structures from the top-most metallization levels in the BEOL stack down to the device level. Within an interconnect structure, conductive vias can run perpendicular to the substrate and conductive lines can run parallel to the substrate.

Patterning processes can include additive and subtractive patterning processes. Additive patterning refers to patterning involving the addition of material to a device (e.g. by deposition), while subtractive patterning refers to patterning involving the removal of material from a device using an etch process. As metal pitches become smaller and pitch lines become thinner, subtractive patterning schemes can be attractive due to, e.g., a lack of conductive liner requirement, and resistance benefits.

### SUMMARY

Aspects of an embodiment of the present invention include a semiconductor structure having a first lower device and a second lower device laterally adjacent to the first lower device at a lower level of the semiconductor structure, a first upper device and a second upper device laterally adjacent to the first upper device at an upper level of the semiconductor structure. The upper level may be vertically above the lower level. The semiconductor structure may also include an angled via electrically connecting the lower device and the first upper device. The angled via may include an angled surface laterally between the first upper device and the second upper device that is angled toward the first upper device relative to a vertical axis

Aspects of an embodiment of the present invention also include a method of fabricating a semiconductor structure. The method may include forming a first source/drain (S/D) and a second S/D, forming a buried power rail (BPR) between the first S/D and the second S/D, and forming a buried power rail via (VBPR) hole. A bottom of the VBPR hole may expose a top of the BPR, and a top of the VBPR hole may be angled toward the first upper device relative to a vertical axis. The method may also include metallizing the VBPR hole to form a VBPR.

Aspects of an embodiment of the present invention may also include a method of fabricating a semiconductor structure. The method may include forming a first lower level wire line and a second lower level wire line at a lower level of the semiconductor structure, forming an angled via opening above the first lower level wire line, forming a first upper level trench and a second upper level trench at an upper level, forming a straight via opening above the second wire line, metallizing the angled via opening to form an angled via, the first upper level trench and the second upper level trench to form a first upper wire line and a second upper level wire line, and the straight via opening to form a straight via.

### BRIEF DESCRIPTION OF THE DRAWINGS

FIG. 1 depicts a schematic top view of a semiconductor structure, in accordance with one embodiment of the present invention;

FIGS. 2A and 2B depict cross-sectional side views of the semiconductor structure of FIG. 1 along lines A-A′ and B-B′ respectively, with like reference numerals referring to like features and at a subsequent fabrication stage of the processing method;

FIGS. 3A and 3B depict cross-sectional side views of the semiconductor structure of FIG. 1 along lines A-A′ and B-B′ respectively, with like reference numerals referring to like features and at a subsequent fabrication stage of the processing method;

FIGS. 4A and 4B depict cross-sectional side views of the semiconductor structure of FIG. 1 along lines A-A′ and B-B′ respectively, with like reference numerals referring to like features and at a subsequent fabrication stage of the processing method;

FIGS. 5A and 5B depict cross-sectional side views of the semiconductor structure of FIG. 1 along lines A-A′ and B-B′ respectively, with like reference numerals referring to like features and at a subsequent fabrication stage of the processing method;

FIGS. 6A and 6B depict cross-sectional side views of the semiconductor structure of FIG. 1 along lines A-A′ and B-B′ respectively, with like reference numerals referring to like features and at a subsequent fabrication stage of the processing method;

FIGS. 7A and 7B depict cross-sectional side views of the semiconductor structure of FIG. 1 along lines A-A′ and B-B′ respectively, with like reference numerals referring to like features and at a subsequent fabrication stage of the processing method;

FIG. 8 depicts a cross-sectional side view of the semiconductor structure of FIG. 1 along line 8-8′, with like reference numerals referring to like features and at a fabrication stage of the processing method;

FIG. 9 depicts a cross-sectional side view of a semiconductor structure, in accordance with an embodiment of the present invention;

FIG. 10 depicts a cross-sectional side view of the semiconductor structure of FIG. 9 at a subsequent fabrication stage, with like reference numerals of previous figures referring to like features;

FIG. 11 depicts a cross-sectional side view of the semiconductor structure of FIG. 9 at a subsequent fabrication stage, with like reference numerals of previous figures referring to like features;

FIG. 12 depicts a cross-sectional side view of the semiconductor structure of FIG. 9 at a subsequent fabrication stage, with like reference numerals of previous figures referring to like features; and

FIG. 13 depicts a cross-sectional side view of the semiconductor structure of FIG. 9 at a subsequent fabrication stage, with like reference numerals of previous figures referring to like features.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface. Typically, the major surface is along a plane of a monocrystalline silicon layer on which transistor devices are fabricated.

Improvements in the design of transistor devices have enabled feature sizes to enter into deep submicron and nanometer regime. These smaller feature sizes, however, can cause otherwise minor issues to have more detrimental effect on the operation of the transistor device. For example, tip to tip shorting can become very difficult to address in small, tight-pitched structures. Specifically, the tips between contacts may be close enough for signals to jump, especially in semiconductor structures that may suffer from misalignment. The difficulty often cannot be addressed by simply reducing the size of the contact due to the desire for the contact to be wide enough to fully cover the contacted device (e.g., source/drain, metal level wire line, power rail).

To reduce shorting between contacts, therefore, semiconductor structures may include an angled via. The angled via may electrically connect a lower device and an upper device, and may include an angled surface that is angled toward the upper device relative to a vertical axis.

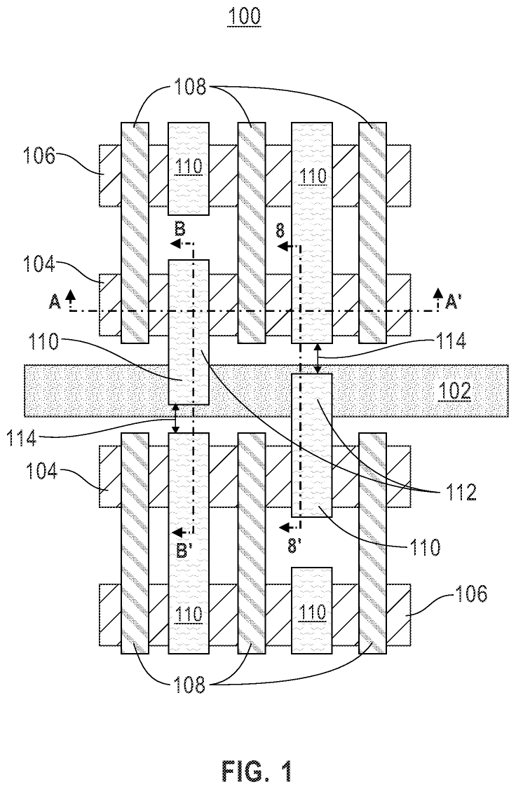

FIG. 1 depicts a schematic top view of a semiconductor structure 100, in accordance with one embodiment of the present invention. The semiconductor structure 100 includes rows of field-effect transistor (FET) devices and columns of gate and source/drain (S/D) devices powered by a buried power rail (BPR) 102. Specifically, the semiconductor structure 100 includes NFETs 104 and PFETs 106, with the BPR 102 running through the semiconductor structure 100 between the NFETs 104. In certain embodiments, the BPR 102 may run between PFETs 106, or between a pair of: one NFET 104 and one PFET 106. The columns include gates 108 and S/D contacts 110 that electrically connect upper devices (e.g., wire lines, metal levels) to the S/Ds and gate structures within the semiconductor structure 100 below. The semiconductor structure 100 also includes buried power rail vias (VBPR) 112 to electrically connect certain S/D contacts 110 to the BPR 102. The VBPR 112 are angled vias that increase a separation distance 114 between the upper devices (i.e., the S/D contacts 110) while fully contacting the lower device (i.e., the BPR 102) as explained in detail below. The semiconductor structure 100 includes other components (e.g., shallow trench isolation, interlayer dielectric) that are not illustrated so that the rows and columns of the semiconductor structure 100 may be more easily described.

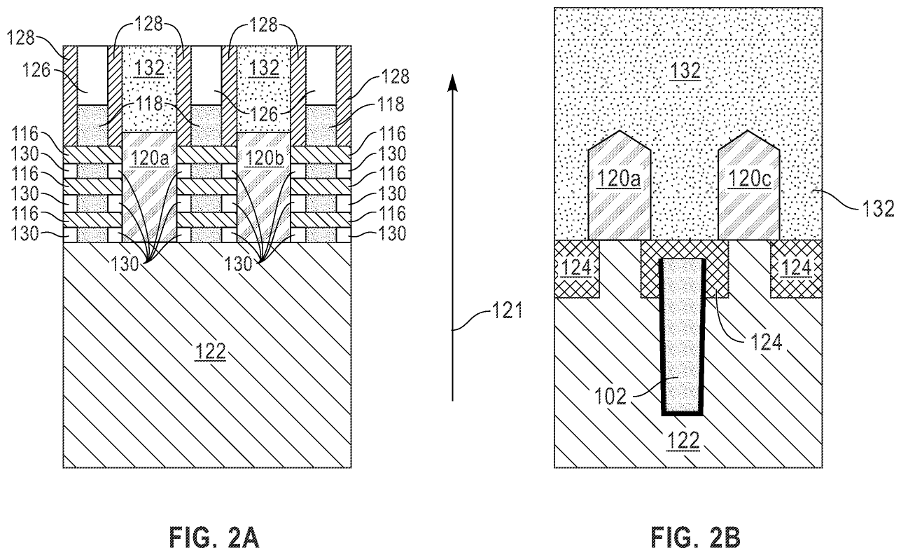

FIGS. 2A and 2B depict cross-sectional side views of the semiconductor structure 100 of FIG. 1 along lines A-A′ and B-B′ respectively, with like reference numerals referring to like features and at a subsequent fabrication stage of the processing method. The semiconductor structure 100 includes nanosheets 116 and high-κ metal gate 118 that are formed in an alternating series as a layer stack along a vertical axis 121 perpendicular to the major surface of a substrate 122. The substrate 122 includes a shallow trench isolation 124, which may be the buried oxide (BOX) layer of a semiconductor-on-insulator (SOI) substrate or dielectric isolation in a bulk substrate. The nanosheets 116 (i.e., nanosheets or nanowires) may be composed of a semiconductor material, such as silicon (Si). The nanosheets 116 may be formed by a known epitaxial growth process. The number of nanosheets 116 and high-κ metal gate 118 may differ (more layers or fewer layers) from the number depicted in the representative embodiment.

A gate dielectric cap 126 is formed on the top of the gate 118. The gate dielectric cap 126 may be composed of a dielectric material, such as silicon nitride, that is deposited (e.g., by chemical vapor deposition (CVD)) followed by chemical-mechanical planarization (CMP) processes). The S/Ds 120, including a first S/D 120a, a second S/D 120b, and a third S/D 120c are separated from the nanosheets 116 and the high-κ metal gate 118 by spacers 128 and inner spacer 134 (both the spacers 128 and the inner spacers 134 may be made of dielectric material, such as SiN, SiBCN, SiOCN, SiOC etc.). The S/Ds 110 are covered by an interlayer dielectric (ILD) 132 that is formed between the S/Ds 110 along one direction (shown in FIG. 2B) and contained by the spacers 128 in a perpendicular direction (shown in FIG. 2A). The ILD 132 may include SiN, SiOx, SiCN, SiCN(H), a low-k dielectric material, or an ultra-low-k dielectric material. The BPR 102 is formed below the S/D epi between NFETs. The BPR 102, in certain embodiments, contains a thin metal adhesion liner such as TiN, TaN and high conductive metals such as Co, W or Ru. In certain embodiments, the BPR 102 includes a dielectric liner that separates the BPR 102 from the substrate 122. In some embodiments, the BPR 102 is not present at this step, and a backside power rail can be formed at end of the process flow after wafer is flipped, followed by substrate removal, backside ILD deposition, backside power rail patterning, and metallization.

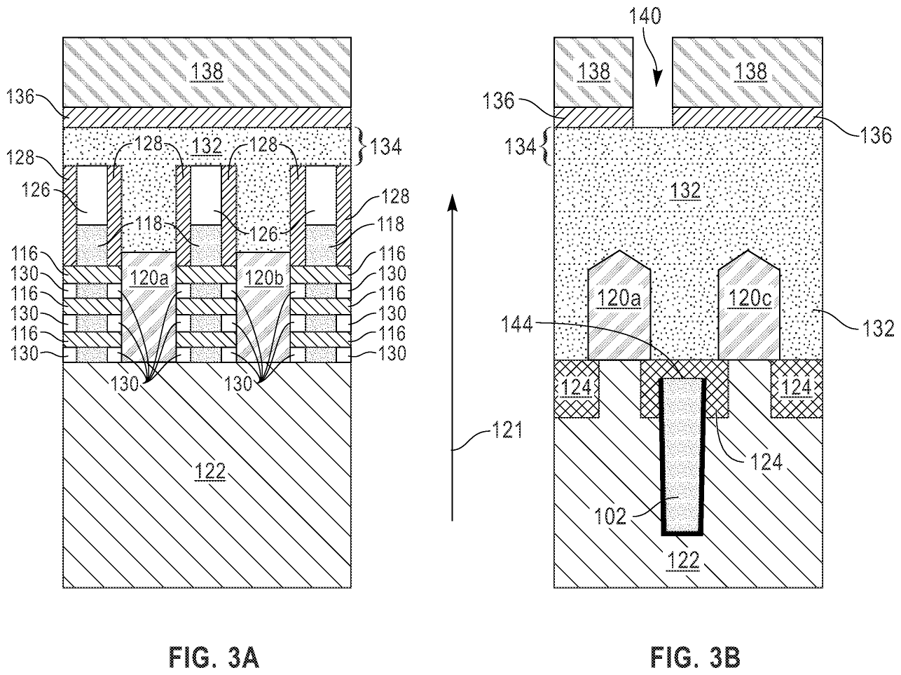

FIGS. 3A and 3B depict cross-sectional side views of the semiconductor structure 100 of FIG. 1 along lines A-A′ and B-B′ respectively, with like reference numerals referring to like features and at a subsequent fabrication stage of the processing method. The semiconductor structure 100 includes an addition 134 of ILD material, a hard mask 136. The addition 134 may vary in thickness among embodiments of the semiconductor structure 100, and in certain embodiments may even include a different material than the ILD 132 formed around the S/Ds 110. The addition 134 and the hard mask 136 may be deposited using known deposition techniques such as chemical vapor deposition (CVD), physical vapor deposition (PVD), or atomic layer deposition (ALD). The hard mask 136 includes a material or materials that may be patterned using, for example, lithographic processes. The semiconductor structure 100 may also include a soft mask layer (e.g. such as organic planarization layer (OPL)) 138 that masks parts of the semiconductor structure 100 during etch processes.

FIG. 3B also shows a VBPR via space 140 patterned and etched into the soft mask layer 138 and hard mask 136. The VBPR via space 140 is formed offset from between the first S/D 120a and the third S/D 120c such that the VBPR via space 140 is at least partially overlapping the area directly above the first S/D 120a (i.e., directly above the first S/D 120a along the vertical axis 121). That is, the VBPR via space 140 in the hard mask 136 is not directly over the BPR 102, but instead enables a via that is angled from the VBPR via space 140 to a top surface 144 of the BPR 102.

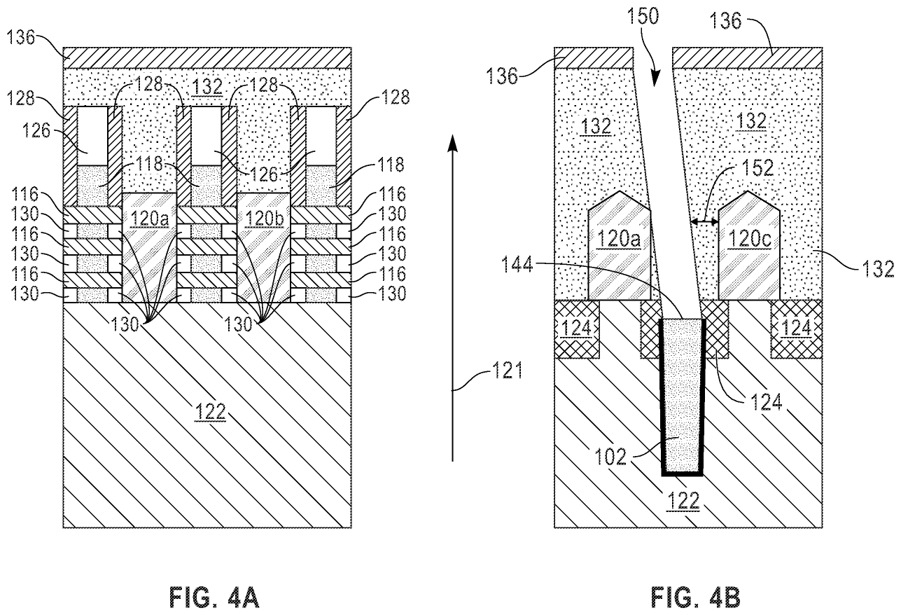

FIGS. 4A and 4B depict cross-sectional side views of the semiconductor structure of FIG. 1 along lines A-A′ and B-B′ respectively, with like reference numerals referring to like features and at a subsequent fabrication stage of the processing method. FIG. 4B shows a VBPR via hole 150 etched down to the top surface 144 of the BPR 102. The VBPR via hole 150 is angled toward the first S/D 110a with respect to the vertical axis 121. This angle of the VBPR via hole 150 increases the distance 152 of the VBPR via hole 150 away from the third S/D 110c with the distance away from the BPR 102. FIG. 4A shows that the gate structures (gates 108, nanosheets 116, metal gate 118, etc.) are not affected by the etching of the VBPR via hole 150. The soft mask layer 138 may also be etched during the etching of the VBPR via hole 150.

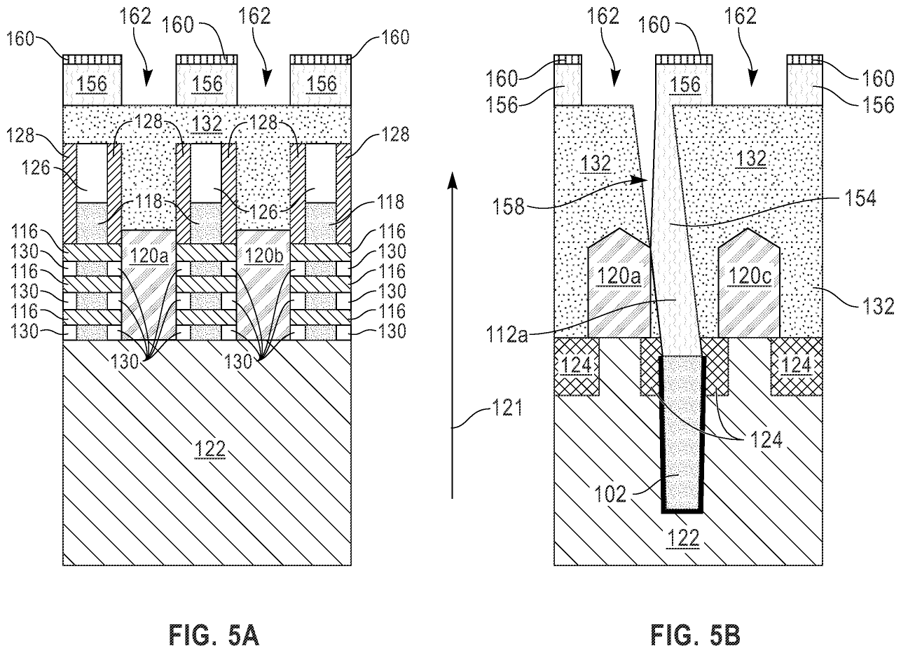

FIGS. 5A and 5B depict cross-sectional side views of the semiconductor structure of FIG. 1 along lines A-A′ and B-B′ respectively, with like reference numerals referring to like features and at a subsequent fabrication stage of the processing method. The semiconductor structure 100 has the hard mask 136 removed, and source/drain contact patterning is performed over an anti-reflective coating (ARC) 160 and OPL 156 using conventional litho and etch process. The OPL 156 is deposited using spin-on coating process which fills the VBPR via hole 150 to protect the underlying BPR during contact patterning. The ARC 160 may include a silicon-containing anti-reflective coating (SiARC).

After the OPL 156, and the ARC 160 are deposited, a contact opening pattern 162 may be etched through the ARC 160 and the OPL 156. The contact opening pattern 162 etches the ARC 160 and the contact masking 156 without etching the ILD 132.

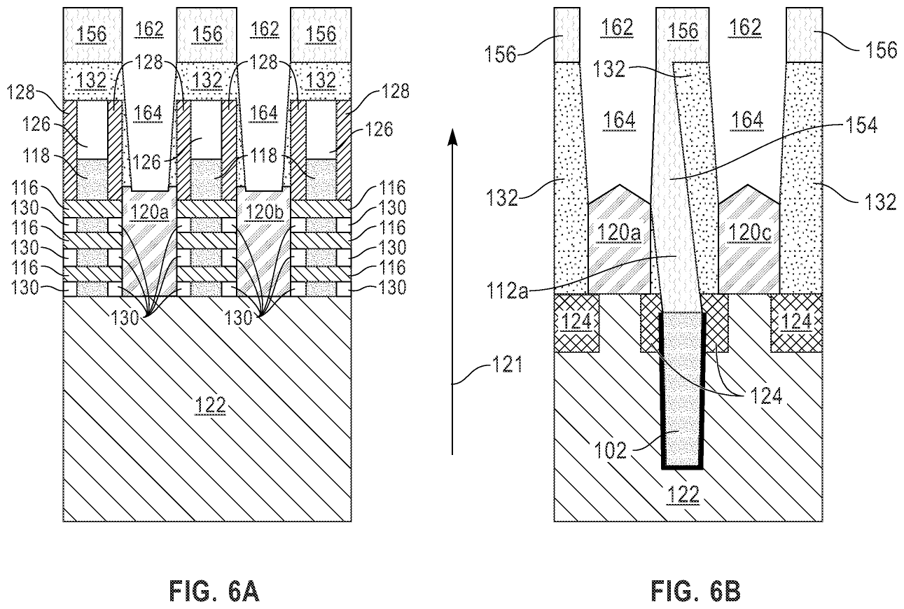

FIGS. 6A and 6B depict cross-sectional side views of the semiconductor structure of FIG. 1 along lines A-A′ and B-B′ respectively, with like reference numerals referring to like features and at a subsequent fabrication stage of the processing method. The semiconductor structure 100 includes contact openings 164 etched into the ILD 132 to expose the S/Ds 120a, b, c. The contact openings 164 may be formed using directed etch techniques such as reactive-ion etch (RIE). During contact etch, the ARC layer is consumed, and the patterned OPL 156 serves as a softmask for the ILD 132 etch. The angled VBPR via hole 150 may be incorporated into the fabrication process without changing the mask pattern for the contact openings 164.

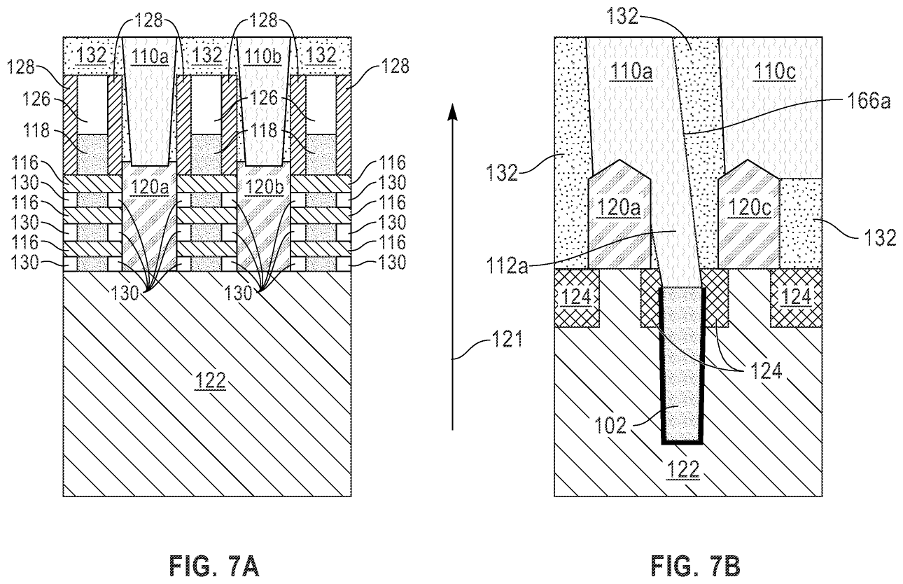

FIGS. 7A and 7B depict cross-sectional side views of the semiconductor structure of FIG. 1 along lines A-A′ and B-B′ respectively, with like reference numerals referring to like features and at a subsequent fabrication stage of the processing method. The semiconductor structure 100 includes metallized S/D contacts 110a, b, c, and the metallized VBPR 112. After S/D contact opening, the OPL 156 is removed by conventional method, such as ashing. The S/D contact 110a for the first S/D 120a merges with the VBPR 112 such that the lower device of the BPR 102 is electrically connected to the upper device of the first S/D 120a. The VBPR 112 includes an angled surface 166 laterally between the first S/D 120a and the third S/D 120c that is angled toward the first S/D 120a relative to the vertical axis 121.

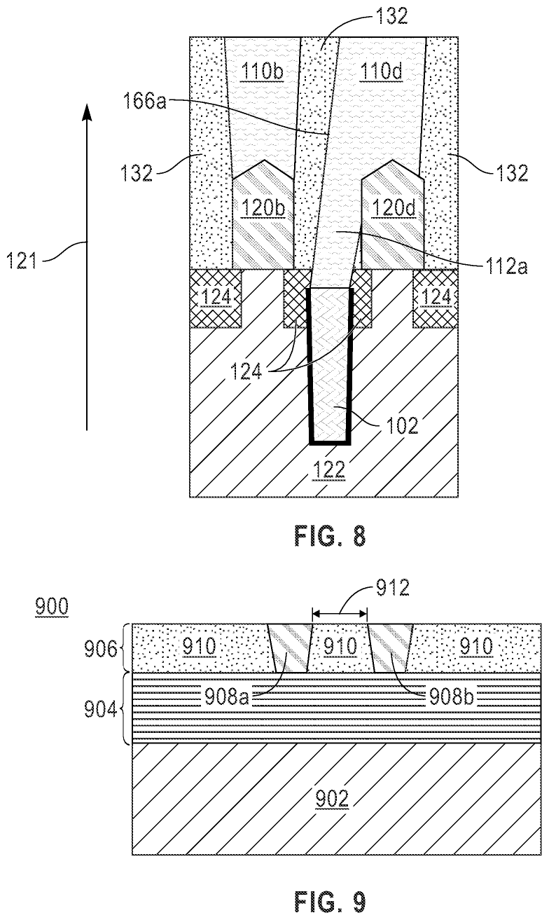

FIG. 8 depicts a cross-sectional side view of the semiconductor structure 100 of FIG. 1 along lines 8-8′, with like reference numerals referring to like features and at the fabrication stage of FIGS. 7A and 7B. FIG. 8 shows a second VBPR 112a that has an angled surface 166a laterally between the second S/D 120b and a fourth S/D 120d that is angled toward a fourth S/D 120d relative to the vertical axis 121. The fourth S/D 120d is located above the same NFET 104 as the second S/D 120b shown in FIGS. 2-7 described above. The second VBPR 112a electrically connects the BPR 102 to the fourth S/D 120d.

FIG. 9 depicts a cross-sectional side view of a semiconductor structure 900, in accordance with one embodiment of the present invention. The semiconductor structure 900 is not necessarily drawn to scale, and includes a substrate 902, device layers 904, and a lower level metal line layer 906. The substrate 902 may include any silicon-containing material including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. The substrate 902 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

The device layers 904 may include any front-end-of-line (FEOL) devices, middle-of-line (MOL) devices, or one or more back-end-of line (BEOL) layers or interconnects as well. The FEOL, MOL, and BEOL devices and layers within the device layers 904 may be formed using traditional semiconductor fabrication practices of deposition, doping, patterning, etching, etc. To connect the device and layers of the device layers 904 together and to external signals and devices, the semiconductor structure 900 includes further BEOL metal layers such as the lower level 906. The lower level metal line 906 includes a first wire line 908a and a second wire line 908b formed within a BEOL interlayer dielectric (ILD) 910. The BEOL ILD 910 may include conventional BEOL ILD stack, such as low-k dielectrics with dielectric constant <3.9.

The wire lines 908a, b may be formed by pattern etching wire line trenches into the BEOL ILD 910 followed by metallization (e.g., copper) of the etched wire line trenches. The wire lines 908a, b connect to devices and/or interconnects in the device layers 904, and the devices and interconnects are increasingly smaller and fabricated at ever tighter pitch. These design constraints mean that a distance 912 between the first wire line 908a and the second wire line 908b must be minimized, but if the distance 912 is too small (i.e., the pitch is too tight) a signal in the first wire line 908a can short to the second wire line 908b, and vice versa.

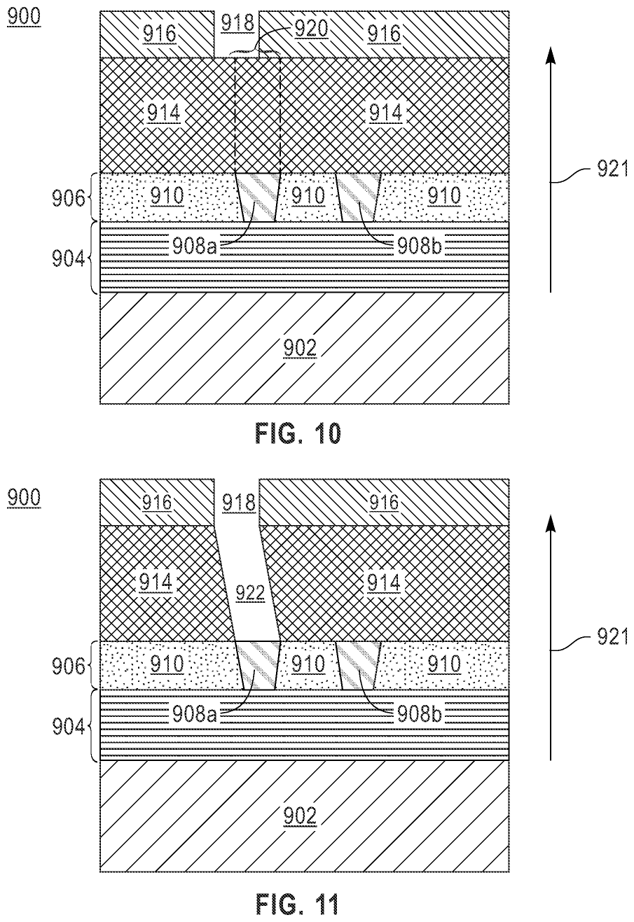

FIG. 10 depicts a cross-sectional side view of the semiconductor structure 900 of FIG. 9, with like reference numerals referring to like features and at a subsequent fabrication stage. The semiconductor structure 900 has added an additional layer of ILD 914 and a hard mask 916. The additional ILD 914 may be added after the lower layer 906 is planarized (e.g., chemical-mechanical planarization CMP). The additional layer 914 may also vary between embodiments in the thickness, and in certain embodiments the additional layer 914 may be the same height as the lower level 906.

The hard mask 916 may be patterned to have a gap 918 for later etching of the angled via. The gap 918 may be located off-center relative to an area 920 directly above the first wire line 908a. As used herein, “directly above” means that the area 920 is over the first wire line 908a as measured along a vertical axis 921.

FIG. 11 depicts a cross-sectional side view of the semiconductor structure 900 of FIG. 9, with like reference numerals referring to like features and at a subsequent fabrication stage. The semiconductor structure 900 includes an angled via opening 922 that connects the gap 918 and the first wire line 908a. The off-center orientation of the gap 918 requires an angled via to connect the gap 918 with the first wire line 908a. The angled via opening 922 is etched through the additional ILD 914 and maximizes the distance away from the second wire line 908b.

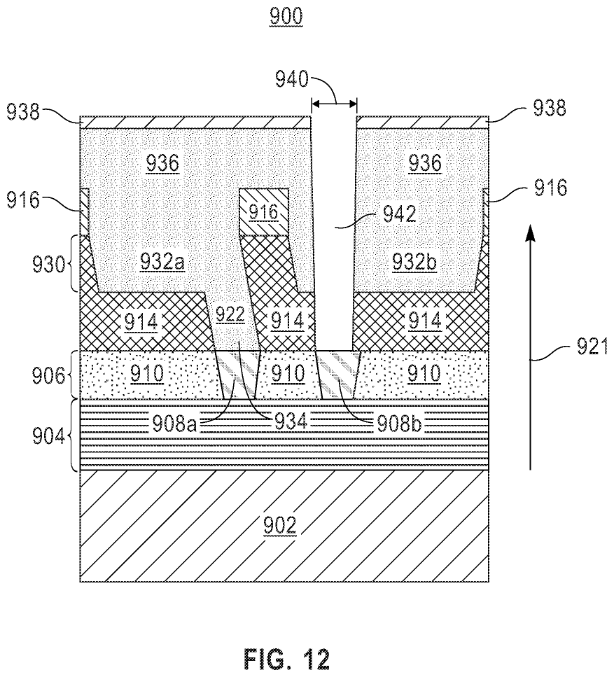

FIG. 12 depicts a cross-sectional side view of the semiconductor structure 900 of FIG. 9, with like reference numerals referring to like features and at a subsequent fabrication stage. The semiconductor structure 900 includes an upper level metal line layer 930 that has upper level trenches 932a, b. and straight via opening 942. They can be patterned by conventional litho and etch process using tri-layer litho stack (including OPL 936, ARC layer 938 and photo-resist.

For the conventional straight via 942, the pattern gap 940 is directly above the second lower level wire line 908b, and the straight via opening 942 is etched straight down (relative to the vertical axis 921) to the second lower level wire line 908b. The straight via opening 942 may be etched through the additional OPL 936 and the additional ILD 914.

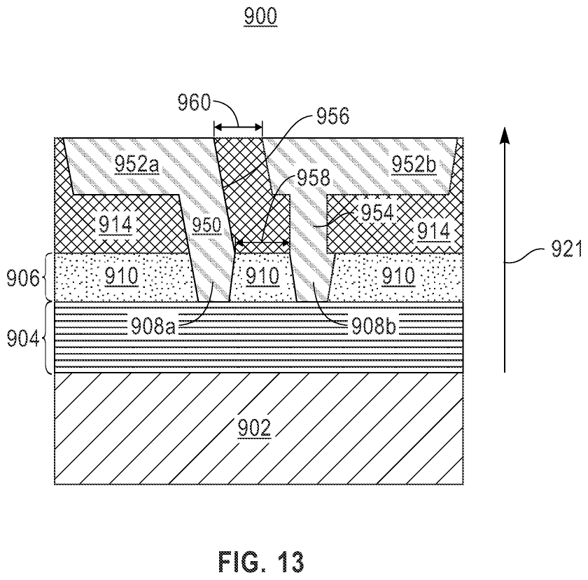

FIG. 13 depicts a cross-sectional side view of the semiconductor structure 900 of FIG. 9, with like reference numerals referring to like features and at a subsequent fabrication stage. The semiconductor structure 900 includes an angled via 950, a first upper wire line 952a, a second upper wire line 952b, and a straight via 954. The OPL 934, additional OPL 936, hard mask 916, and ARC 938 have been removed from the semiconductor structure 900, leaving the additional ILD 914 to support the metallized angled via 950, first upper wire line 952a, second upper wire line 952b, and straight via 954. The angled via 950 includes an angled surface 956 laterally between the first upper wire line 952a and the second upper wire line 952b. The angled surface 956 is angled toward the first upper wire line 952a relative to the vertical axis 921. The angled via 950 is also formed so that a distance 960 between the first upper level wire line 952a and the second upper level wire line 952b is at least as great as a distance 958 between the first lower level wire line 908a and the second lower level wire line 908b.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first lower device at a lower level of the semiconductor structure;
a first upper device at an upper level of the semiconductor structure
a second upper device laterally adjacent to the first upper device at the upper level, wherein the upper level is vertically above the lower level;
an angled via electrically connecting the first lower device and the first upper device, wherein the angled via comprises an angled surface laterally between the first upper device and the second upper device that is angled toward the first upper device relative to a vertical axis.

2. The semiconductor structure of claim 1, wherein the first lower device is a buried power rail.

3. The semiconductor structure of claim 2, wherein the first upper device is a source/drain.

4. The semiconductor structure of claim 1, wherein a distance between the angled via and the second upper device is at least as great as a distance between the angled via and the second lower device.

5. The semiconductor structure of claim 1, wherein the first lower device is a first wire line of a lower back end of line (BEOL) metal layer and the first upper device is a wire line of an upper BEOL metal layer.

6. The semiconductor structure of claim 5, further comprising:
a second wire line at the lower BEOL metal layer; and
a straight via electrically connecting the second wire line and the second upper device.

7. A method of fabricating a semiconductor structure, comprising:
forming a first source/drain (S/D) and a second S/D;
forming a buried power rail (BPR) between the first S/D and the second S/D;
forming a buried power rail via (VBPR) hole, wherein a bottom of the VBPR hole exposes a top of the BPR, and a top of the VBPR hole angled toward the first upper device relative to a vertical axis; and
metallizing the VBPR hole to form a VBPR.

8. The method of claim 7, further comprising:
forming an interlayer dielectric (ILD) around the first S/D and the second S/D;
forming a hard mask over the ILD;
patterning the hard mask, wherein the pattern comprises a VBPR via space that is at least partially overlapping an area directly above the first S/D, and wherein forming the VBPR hole comprises etching the ILD between the VBPR via space and the BPR.

9. The method of claim 7, further comprising:
etching a first S/D contact hole and a second S/D contact hole;
metallizing the first S/D contact hole to form a first S/D contact, wherein the first S/D contact and the VBPR are metallized concurrently.

10. The method of claim 9, further comprising filling, at least partially, the VBPR hole with an organic planarization layer (OPL) before etching the first S/D contact hole.

11. The method of claim 7, further comprising:
forming a second VBPR hole wherein a bottom of the second VBPR hole exposes the top of the BPR, and a top of the second VBPR hole is closer to a third S/D, and wherein the third S/D is located above a field-effect transistor (FET) row that is below the second S/D.

12. The method of claim 11, further comprising metallizing the second VBPR hole to form a second VBPR.

13. The method of claim 7, wherein the VBPR comprises an angled surface laterally between the first S/D and the second S/D that is angled toward the first S/D relative to a vertical axis.

14. A method of fabricating a semiconductor structure, comprising:
forming a first lower level wire line and a second lower level wire line at a lower level of the semiconductor structure;
forming an angled via opening above the first lower level wire line;
forming a first upper level trench and a second upper level trench at an upper level;
forming a straight via opening above the second wire line; and
metallizing the angled via opening to form an angled via, the first upper level trench and the second upper level trench to form a first upper wire line and a second upper level wire line, and the straight via opening to form a straight via.

15. The method of claim 14, wherein forming the angled via opening comprises forming a hard mask gap that is offset from the first lower level wire line.

16. The method of claim 14, further comprising at least partially filling the angled via opening with an organic planarization layer before forming the upper level trenches.

17. The method of claim 14, further comprising at least partially filling the upper level trenches with an organic planarization layer before forming the straight via.

18. The method of claim 14, wherein a distance between the first upper level wire line and the second upper level wire line is at least as great as a distance between the first lower level wire line and the second lower level wire line.

19. The method of claim 14, wherein the angled via comprises an angled surface laterally between the first upper level wire line and the second upper level wire line that is angled toward the first upper level wire line relative to a vertical axis.

20. The method of claim 14, filling, at least partially, the angled via opening with an organic planarization layer (OPL) before forming the straight via opening.
